(19) United States
(12) Patent Application Publication
(10) Pub. No.: US 2017/0098760 A1
(43) Pub. Date: Apr. 6, 2017

(54) TRANSITION METAL DICHALCOGENIDE-BASED SPINTRONICS DEVICES

(71) Applicants: National University of Singapore, Singapore (SG); National Sun Yat-Sen University, Kaohsiung (TW); National Tsing Hua University, Hsinchu (TW); Northeastern University, Boston, MA (US)

(72) Inventors: Hsin Lin, Singapore (SG); Wei-Feng Tsai, Kaohsiung (TW); Cheng-Yi Huang, Kaohsiung (TW); Horng-Tay Jeng, Hsinchu (TW); Tay-Rong Chang, Singapore (SG); Gaurav Gupta, Singapore (SG); Gengchiau Liang, Singapore (SG); Arun Bansil, Boston, MA (US)

(21) Appl. No.: 15/283,609

(22) Filed: Oct. 3, 2016

Related U.S. Application Data
(60) Provisional application No. 62/236,533, filed on Oct. 2, 2015.

(51) Int. Cl. H01L 43/02; H01L 43/10

(52) U.S. Cl. CPC H01L 43/02; H01L 43/10

(57) ABSTRACT

Transition metal dichalcogenide (TMD)-based spintronics devices, each including a TMD thin film layer, a first gate electrode, a first insulating layer sandwiched between the TMD thin film layer and the first gate electrode, a second gate electrode, and a second insulating layer sandwiched between the TMD thin film layer and the second gate electrode. Such a device, when also including a source electrode and a drain electrode, functions as a spin filter. On the other hand, when also including one source electrode and two drain electrode terminals, such a device functions as a spin separator. Also disclosed are methods of using the above-described TMD-based spintronics devices.

### CROSS REFERENCE TO RELATED APPLICATIONS

This application claims priority to U.S. Provisional Application No. 62/236,533 filed on Oct. 2, 2015, the content of which is incorporated herein in its entirety.

### BACKGROUND OF THE INVENTION

Spin polarization, measured by the degree to which the spin (i.e., the intrinsic angular momentum of elementary particles) is aligned with a given direction, is of fundamental importance to the spintronics industry. The performance of spintronics devices, e.g., a spin filter and a spin separator, is determined by the degree of spin polarization and the controllability thereof.

Transition metal dichalcogenide (TMD) has emerged as a promising material for spintronics applications. Representative TMD compounds include MoS₂, MoSe₂, MoTe₂, WS₂, WSe₂, and WTe₂. Yet, a tunable spintronics device built on TMD has not been perfected.

There is a need to develop high-performance TMD-based spintronics devices.

### SUMMARY OF THE INVENTION

This invention provides TMD-based spintronics devices that are tunable and electric gate-controlled. In these devices, widely separated spin-polarized electronic states can be induced, allowing highly efficient production of spin-polarized current.

One aspect of this invention relates to a TMD-based spintronics device for use as a spin filter. This device includes: (i) a TMD thin film having a first surface and a second surface opposed to each other, (ii) a source electrode, (iii) a drain electrode, (iv) a first gate electrode, (v) a first insulating layer covering the first surface and disposed between the TMD thin film and the first gate electrode, (vi) a second gate electrode, and (vii) a second insulating layer covering the second surface and disposed between the TMD thin film and the second gate electrode. The TMD thin film, containing one or more TMD layers, is disposed between, and in electric contact with the source electrode and the drain electrode.

In another aspect, the invention relates to a TMD-based spintronics device for use as a spin separator. This device includes: (i) a TMD thin film having a first surface and a second surface opposed to each other, (ii) a first gate electrode, (iii) a first insulating layer covering the first surface and disposed between the TMD thin film and the first gate electrode, (iv) a second gate electrode, (v) a second insulating layer covering the second surface and disposed between the TMD thin film and the second gate electrode, and (vi) a first electrode terminal, a second electrode terminal, and a third electrode terminal. The TMD thin film contains one or more TMD layers and each of the three electrode terminals are in electric contact with the thin film.

The TMD thin film is 0.3 to 100 nm (e.g., 0.3-5 nm, 5-10 nm, 10-20 nm, and 20-40 nm) in thickness. Each TMD layer in the thin film can be made of a single molecular layer of MX₂, in which M is a transition metal or a transition metal alloy, e.g., Mo, W, Nb, Ta, and Mo(10%)-W(90%), and X is a chalcogen or a mixture thereof, e.g., S, Se, Te, and Se(50%)-Te(50%).

The TMD thin film can have an odd number of TMD layers, e.g., three layers, or an even number of TMD layers, e.g., two layers.

The first insulating layer and the second insulating layer are, independently, made of a dielectric material or a magnetic insulator. Examples of the dielectric material include glass, silicon, magnesia, sapphire, and a polymer. The magnetic insulator can be Ni—Co—Fe oxide, Ni—Co—Fe boride, EuO, EuS, EuSe, EuTe, or Yttrium iron garnet.

The invention also covers a method of using the above-described spin filter. The method includes the following three steps: (i) applying a voltage between the first gate electrode and the second gate electrode to induce an electric field or a magnetic field in the TMD thin film, (ii) tuning the voltage so that electrons emitted from the TMD thin film are spin-polarized, and (iii) supplying an electric input to the source electrode to obtain a spin-polarized electric output at the drain electrode from the TMD thin film in response to the electric input.

Also included in this invention is a method of using the above-described spin separator. The method includes three steps: (i) applying a voltage between the first gate electrode and the second gate electrode to induce an electric field or a magnetic field in the TMD thin film, (ii) tuning the voltage so that electrons emitted from the TMD thin film are spin-polarized, and (iii) supplying an electric input to the first electrode terminal to obtain two spin-polarized electric outputs having opposite spins at the second and third electrode terminals from the TMD thin film in response to the electric input.

The details of the invention are set forth in the drawings and the description below. Other features, objects, and advantages of the invention will be apparent from the drawing and the description, as well as from the appended claims.

### BRIEF DESCRIPTION OF THE DRAWINGS

FIG. 1 is a schematic diagram illustrating a TMD-based spintronics device in accordance with the teachings of the present invention.

FIG. 2 is a schematic diagram showing (i) the geometry of a spintronics device for use as a spin filter and (ii) a plot of applied gating potential (U) vs. location (X) along the length of the device.

FIG. 3 is a schematic diagram showing the geometry of a U-shaped spintronics device for use as a spin separator.

### DETAILED DESCRIPTION

The invention provides TMD-based spintronics devices that are tunable and controlled by an electric gate. Also included in the invention are methods of using such devices.

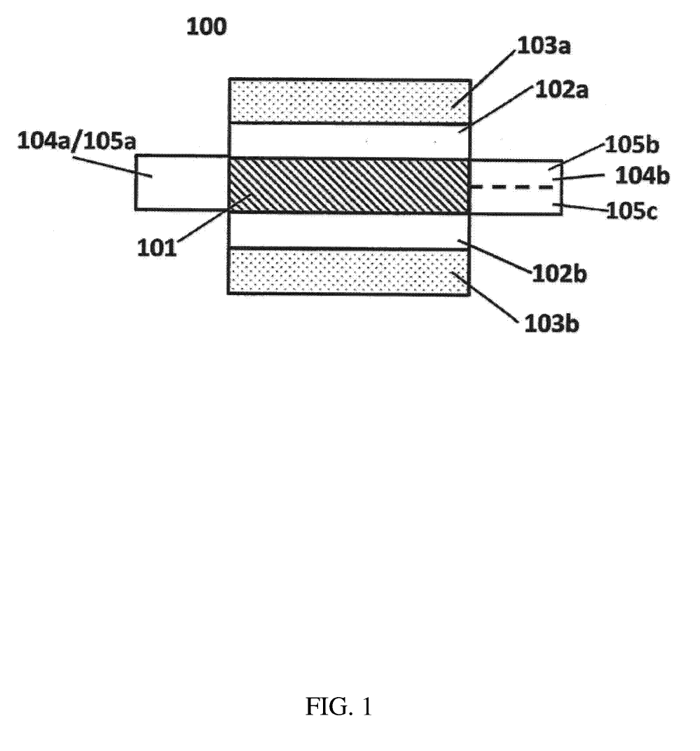

A schematic diagram of the TMD-based spintronics device of this invention, for use both as a spin filter and a spin separator, is shown in FIG. 1. The spintronics device 100 includes a TMD thin film layer 101, a first gate electrode 103a, a first insulating layer 102a sandwiched between the TMD thin film layer 101 and the first gate electrode 103a, a second gate electrode 103b, and a second insulating layer 102b sandwiched between the TMD thin film layer 101 and the second gate electrode 103b. The first insulating layer 102a and the second insulating layer 102b are both made of a dielectric material or a magnetic insulator.

The spintronics device 100 is a spin filter when it also includes a source electrode 104a and a drain electrode 104b, both of which are in electric contact with the TMD thin film layer 101.

On the other hand, the spintronics device 100 is a spin separator when it also includes three electrode terminals 105a, 105b, and 105c, each of which is in electric contact with the TMD thin film layer 101.

TMD is a layered material, which crystallizes with space group P6₃/mmc. Each unit cell in a TMD crystal contains two inverse MX₂ layers. In each MX₂ layer, M can be a transition metal or a transition metal alloy, e.g., Mo, W, Nb, Ta, and Mo(10%)-W(90%); and X can be a chalcogen or a mixture thereof, e.g., S, Se, Te, and Se(50%)-Te(50%). The intermediate M atom is sandwiched by two X atoms, forming a trigonal prism local structure. The van der Waals force between two adjacent MX₂ layers of a TMD is weak. As such, a TMD can be easily exfoliated mechanically to yield single MX₂ layers. In a multilayer MX₂, individual layers can be identical or different from one another.

In a TMD film, (i) inversion symmetry is absent when there is a single or odd number of MX₂ layers, and (ii) there is strong spin-orbit coupling (SOC) arising from the d-orbital nature of the electrons of M. A spintronics device of this invention, either a spin filter or a spin separator, takes advantage of these two features of a TMD film. A spin filter enables an output current with high spin polarization of at least 68%, e.g., at least 78%, at least 88%, at least 98%, and 100%. On the other hand, a spin separator efficiently steers a source current into two output drain terminals with opposite spin polarization.

In a TMD thin film, band gap range from indirect for multilayer MX₂, to direct for an MX₂ monolayer. See K. F. Mak et al., 2010, Phys. Rev. Lett. 105, 136805. In an MX₂ monolayer, due to finite SOC, valence bands at the top of electronic band structure exhibit energy splitting between up and down spin states of 100-500 meV around the high symmetry K and K′ points of the first Brillouin zone. These two points represent two inequivalent valleys resulting from the large separation between them in momentum space. By manipulating these two valleys so that one is deeper than the other, one can make electrons populate only one of the two valleys, thereby vastly improving and greatly expanding applications in valleytronics. See D. Xiao et al., 2012, Phys. Rev. Lett. 108. 196802.

The valence band energy splitting achievable in an MX₂ monolayer is substantially higher than that achieved in 2D materials such as silicene or other group IVA counterparts. See Tsai, W.-F. et al., 2013, Nature Communications, 4, 1500. It is also sufficiently large to make an MX₂ monolayer useful for room temperature applications.

In the absence of inversion symmetry, top valence bands at K and K′ points split into two spin polarized states with opposite spins. Further, when an exchange field or an out-of-plane magnetic field is applied, the two spin polarized states shift in energy in opposite directions. Under this condition, one can place the Fermi level going through the valence bands around only one of the K and K′ points so that the conducting electrons are highly spin polarized with at least 68% out-of-plane spin polarization. This can be achieved by hole doping or electric gating. If the Fermi level is moved to an energy level at which both K and K′ point valence bands are present, the spin polarization from one point cancels that from the other. As a result, the conducting electrons have reduced spin polarization. The exchange field can be realized by magnetic doping or placing a TMD thin film on a magnetic substrate. Further, both the energy splitting and the Fermi level can be controlled by electric gating.

In a single-layer MX₂ or in a multilayer MX₂ having an odd number of layers, the lack of the inversion symmetry, combined with SOC, leads automatically to energy-splitting of the valence bands at K and K′ points without the need for an external magnetic field.

On the other hand, in a multilayer MX₂ having an even number of layers, inversion symmetry can be broken by adding an out-of-plane electric field through gating, by placing the TMD thin film on a substrate, or by growing the film as a heterostructure without inversion symmetry.

TMD thin films having either an odd or even number of MX₂ layers (i.e., TMD layers) are suitable for use in the tunable spintronics devices described above.

As pointed out above, a TMD thin film-containing spintronics device of this invention functions as a spin filter when it includes a source electrode and a drain electrode. This spin filter is operational when an out-of-plane magnetic field or an exchange field is present. By adjusting the voltage between the first gate electrode and the second gate electrode, the Fermi level of electrons emitted from the TMD thin film can be tuned so that, when a current enters the spin filter from the source electrode, at least 68% spin polarized output current can be obtained at the drain electrode. The degree of the spin polarization of the output current can be reduced or eliminated by tuning the Fermi level using the gate voltage without the need to switch magnetic field.

As also pointed out above, a TMD thin film-containing spintronics device of this invention functions as a spin separator when it includes three electrode terminals, i.e., a first electrode terminal, a second electrode terminal, and a third electrode terminal. By tuning the voltage between the first gate electrode and the second gate electrode of this spin separator, the Fermi level of electrons emitted from the TMD thin film can be tuned so that, when an electric input is supplied to the first electrode terminal, two electric outputs, both spin-polarized but having opposite spins, can be obtained at the second and third electrode terminals.

The spin separator can have different shapes, e.g., Y shape, U shape, or any other shape affording three spatially separated terminals. Moreover, the spin separator can be used for logical circuits under room temperature beyond binary operations.

The TMD-based devices described above have applications in several areas. Examples include (i) digital electronics, e.g., field effect transistors, invertors, and logic gates; (ii) optoelectronics, e.g., photodetectors, solar cells, and light emitting diodes; and (3) electronic sensors for detecting an analyte.

Without further elaboration, it is believed that one skilled in the art can, based on the above description, utilize the present invention to its fullest extent. The following two exemplary embodiments are, therefore, to be construed as merely illustrative and not limitative of the remainder of the disclosure in any way whatsoever. All publications cited herein are incorporated by reference.

### Example 1: Spin Filter

Described below is a 2 dimensional device of the invention for use as a spin filter. It consists of a quantum point contact (QPC) in a thin film of MoS₂ monolayer with zigzag edges.

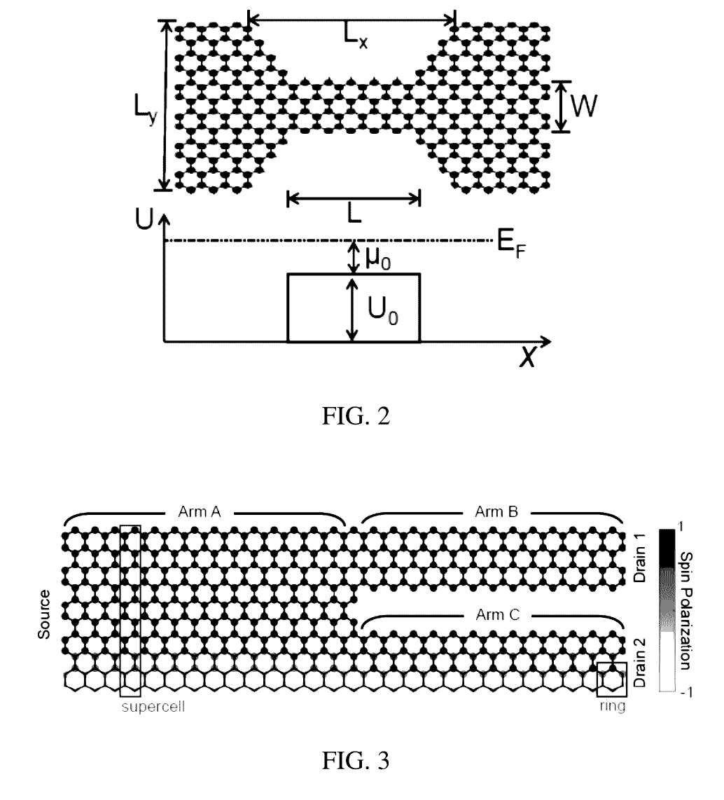

The device, a schematic diagram of which is shown in FIG. 2, has two wide regions, one on each side of a confined constriction region having length L. FIG. 2 also shows that both wide regions gradually narrow toward the confined constriction region, thereby defining an expansive constriction region having length Lₓ. One wide region serves as a source for incoming current and the other as a drain for output current.

Geometry of the QPC was set as follows: width of each wide region L_{y}=70√3a, (a=3.193 Å); length of the confined constriction region L=36a; width of the confined constriction region W=20√3a; and length of the expansive constriction region Lₓ=86a. See FIG. 2. Also included in FIG. 2 is a plot of gating potential (U) vs. location (X). It shows the magnitude of the potential (U) applied to operate the device.

The two opposite wide regions were arranged with a Fermi level E_{F} (FIG. 2) of −0.85 eV to model a metallic source and drain. Note that the source contains both spin polarizations. In the confined constriction region, an exchange field, h=0.05 eV, was applied to make the valence bands around K and K′ points shifted in energy in opposite directions. Next, gating potential U₀ (FIG. 2) was adjusted within the middle constriction region such that the effective Fermi level μ₀, (i.e., E_{F}-U₀; FIG. 2) intersected the valence bands at only one of either K or K′ point.

Quantum transport simulations were carried out to determine the extent of spin polarization obtained using this device. Two-terminal conductance of the QCP was calculated by the Landauer formula

$$G = \frac{{e}^{2}}{h} {Σ}_{μ v} {\vert {t}_{μ v} \vert}^{2} ≡ {T}_{↑} + {T}_{↓} ,$$

where the spin-resolved transmission probability

$${T}_{↑ ( ↓ )} = \frac{{e}^{2}}{h} {Σ}_{m ∈ ↑ ( ↓ )} {Σ}_{n} {\vert {t}_{mn} \vert}^{2} ,$$

m and n representing outgoing and incoming channels, respectively. Each transmission matrix element tₘₙ was computed numerically by the iterative Greens function method. See T. Ando, 1991, Phys. Rev. B 44, 8017-8027. Spin polarization was expressed as

$$P = \frac{{T}_{↑} - {T}_{↓}}{{T}_{↑} + {T}_{↓}} .$$

For 0<P≦1, the transmitted current was polarized with spin-up holes, while for −1≦P<0, the polarization was reversed.

Spin polarization, calculated as a function of μ₀, clearly demonstrated that, for −0.85 eV<μ₀<−0.75 eV, current flowed entirely within the valence band of only one of K and K′ points, with polarization at the drain unexpectedly reaching almost 100%. In other words, the above-described device functions as an excellent spin filter.

By locally changing the potential barrier in the constricted region through gating control, the degree of spin polarization can be reduced or eliminated by tuning the effective Fermi level to also cross the point with the opposite spin. Simulations showed that, for μ₀<−0.85 eV, polarization dropped or even became reversed due to contribution from the other point.

### Example 2: Spin Separator

A spintronics device of the invention for use as a spin separator is described below. The spin separator can be obtained by replacing the drain of the spin filter described in Example 1 by two spatially separated terminals.

The spin separator, a schematic diagram of which is shown in FIG. 3, includes a MoS₂ monolayer thin film with three arms, Arm A, Arm B, and Arm C, which have terminal A (Source), terminal B (Drain 1), and terminal C (Drain 2), respectively. Terminal A serves as an input terminal and terminals B and C serve as output terminals.

A double-gate, sandwiching the MoS₂ thin film in the center, is applied to control both the Fermi level E_{F} and the out-of-the plane electric field. The device is U-shaped (FIG. 3). Other shapes, e.g., Y shape or another shape with three terminals, can be used. It can separate the two spin polarizations present at input terminal A (Source), with one running to output terminal B (Drain 1) and the other running to output terminal C (Drain 2).

This spin separator is operated as follows. First, in the MoS₂ thin film, chemical potential is tuned into valence bands by gating. Then, a source-to-drain voltage is applied by setting potentials V_{A}, V_{B}, and V_{C}, respectively, at terminals A, B, and C, such that V_{A}>V_{B}=V_{C}. This setup leads to spin polarization imbalance at output terminals B and C.

The device was tested by performing quantum transport simulation to determine spin separation in the output currents using the non-equilibrium Greens function method. See S. Datta, Quantom Transport: Atom to Transistor, 2005, Cambridge University Press. Of note, in this device, the width of the source terminal (Source; FIG. 3) is 5-ring units, and that of each of the drain terminals (Drains 1 and 2; FIG. 3) is 2-ring units. See FIG. 3 for a depiction of a ring unit. Also note that each arm has a scattering region of 10 supercells, and the source and drain regions are extended to infinity. See FIG. 3 for a depiction of a supercell. Finally, the source-to-drain voltage was set to V_{A}−V_{B}=1 mV (V_{B}=V_{C}) to capture the device behavior for narrow energy windows.

Current Iᵢ and spin polarization (P_{z})ᵢ at each arm were calculated based on the following formulas:

$${I}_{i} = \frac{e}{h} {\int }_{- ∞}^{∞} {\sum }_{j} Tr ( {Γ}_{i} {G}^{R} {Γ}_{j} {G}^{A} ) ( {f}_{i} - {f}_{j} ) d E , \\ {( {P}_{z} )}_{i} = \frac{{\int }_{- ∞}^{∞} {\sum }_{j} Tr ( {Σ}_{z} [ {Γ}_{i} {G}^{R} {Γ}_{j} {G}^{A} ] ) ( {f}_{i} - {f}_{j} ) d E}{{\int }_{- ∞}^{∞} {\sum }_{j} Tr ( {Γ}_{i} {G}^{R} {Γ}_{j} {G}^{A} ) ( {f}_{i} - {f}_{j} ) d E} ,$$

Results obtained from the calculations show that the device exhibited spin separation and generated spin-polarized current in the arms. Indeed, at one of the arms, 100% spin polarization was unexpectedly obtained over a large energy window. In other words, the device functions as an excellent spin separator.

Further, these calculations indicated that transmission became significant only when the Fermi level E_{F} was lowered to meet the valence subband of Arm B. With the transmission, an asymmetry of spin polarization at Arm B and Arm C was observed. The asymmetry of spin polarization arose from the asymmetric density of states in different sublattices (or different species of atoms) due to the presence of an effective perpendicular electric field resulting from the intrinsic absence of inversion in an MX₂ monolayer.

### Other Embodiments

All of the features disclosed in this specification may be combined in any combination. Each feature disclosed in this specification may be replaced by an alternative feature serving the same, equivalent, or similar purpose. Thus, unless expressly stated otherwise, each feature disclosed is only an example of a generic series of equivalent or similar features.

Further, from the above description, one skilled in the art can easily ascertain the essential characteristics of the present invention, and without departing from the spirit and scope thereof, can make various changes and modifications of the invention to adapt it to various usages and conditions. Thus, other embodiments are also within the claims.

1. A spintronics device comprising:
a transition metal dichalcogenide (TMD) thin film that contains one or more TMD layers and is 0.3 to 100 nm in thickness, the film having a first surface and a second surface opposed to each other;
a source electrode;
a drain electrode;
a first gate electrode;
a first insulating layer covering the first surface and disposed between the TMD thin film and the first gate electrode;
a second gate electrode; and
a second insulating layer covering the second surface and disposed between the TMD thin film and the second gate electrode,
wherein the TMD thin film is disposed between the source electrode and the drain electrode, and is in electric contact with both the source electrode and the drain electrode.

2. The spintronics device of claim 1, wherein each of the one or more TMD layers is made of a single molecular layer of MX₂, wherein M is a transition metal or a transition metal alloy and X is a chalcogen or a mixture thereof.

3. The spintronics device of claim 2, wherein the transition metal or the transition metal alloy is selected from the group consisting of Mo, W, Nb, Ta, and Mo(10%)-W(90%); and the chalcogen or a mixture thereof is selected from the group consisting of S, Se, Te, and Se(50%)-Te(50%).

4. The spintronics device of claim 2, wherein the TMD thin film contains one TMD layer.

5. The spintronics device of claim 2, wherein the TMD thin film contains two TMD layers.

6. The spintronics device of claim 1, wherein the first insulating layer and the second insulating layer are, independently, made of a dielectric material or a magnetic insulator.

7. The spintronics device of claim 6, wherein the dielectric material is glass, silicon, magnesia, sapphire, or a polymer.

8. The spintronics device of claim 6, wherein the magnetic insulator is Ni—Co—Fe oxide, Ni—Co—Fe boride, EuO, EuS, EuSe, EuTe, or Yttrium iron garnet.

9. The spintronics device of claim 2, wherein the first insulating layer and the second insulating layer are, independently, made of a dielectric material or a magnetic insulator.

10. The spintronics device of claim 4, wherein the first insulating layer and the second insulating layer are, independently, made of a dielectric material or a magnetic insulator.

11. A spintronics device comprising:
a transition metal dichalcogenide (TMD) thin film that contains one or more TMD layers and is 0.3 to 100 nm in thickness, the film having a first surface and a second surface opposed to each other;
a first gate electrode;
a first insulating layer covering the first surface and disposed between the TMD thin film and the first gate electrode;
a second gate electrode;
a second insulating layer covering the second surface and disposed between the TMD thin film and the second gate electrode;
a first electrode terminal;
a second electrode terminal; and
a third electrode terminal,
wherein the three electrode terminals are each in electric contact with the TMD thin film.

12. The spintronics device of claim 11, wherein each of the one or more TMD layers is made of a single molecular layer of MX₂, wherein M is a transition metal or a transition metal alloy and X is a chalcogen or a mixture thereof.

13. The spintronics device of claim 12, wherein the transition metal or the transition metal alloy is selected from the group consisting of Mo, W, Nb, Ta, and Mo(10%)-W(90%); and the chalcogen or a mixture thereof is selected from the group consisting of S, Se, Te, and Se(50%)-Te(50%).

14. The spintronics device of claim 12, wherein the TMD thin film contains one TMD layer.

15. The spintronics device of claim 12, wherein the TMD thin film contains two TMD layers.

16. The spintronics device of claim 11, wherein the first insulating layer and the second insulating layer are, independently, made of a dielectric material or a magnetic insulator.

17. The spintronics device of claim 16, wherein the dielectric material is glass, silicon, magnesia, sapphire, or a polymer.

18. The spintronics device of claim 16, wherein the magnetic insulator is Ni—Co—Fe oxide, Ni—Co—Fe boride, EuO, EuS, EuSe, EuTe, or Yttrium iron garnet.

19. The spintronics device of claim 12, wherein the first insulating layer and the second insulating layer are, independently, made of a dielectric material or a magnetic insulator.

20. The spintronics device of claim 14, wherein the first insulating layer and the second insulating layer are, independently, made of a dielectric material or a magnetic insulator.

21. A method of using the spintronics device of claim 1, comprising:
applying a voltage between the first gate electrode and the second gate electrode to induce an electric field or a magnetic field in the TMD thin film;
tuning the voltage so that electrons emitted from the TMD thin film are spin-polarized; and
supplying an electric input to the source electrode to obtain a spin-polarized electric output at the drain electrode from the TMD thin film in response to the electric input.

22. A method of using the spintronics device of claim 11, comprising:
applying a voltage between the first gate electrode and the second gate electrode to induce an electric field or a magnetic field effect in the TMD thin film;
tuning the voltage so that electrons emitted from the TMD thin film are spin-polarized; and
supplying an electric input to the first electrode terminal to obtain two spin-polarized electric outputs having opposite spins at the second and third electrode terminals from the TMD thin film in response to the electric input.
